(19) United States
(12) Patent Application Publication
(10) Pub. No.: US 2026/0052686 A1
(43) Pub. Date: Feb. 19, 2026

(54) MANAGING CONTACT STRUCTURES IN SEMICONDUCTOR DEVICES

(71) Applicant: Yangtze Memory Technologies Co., Ltd., Wuhan (CN)

(72) Inventors: Jiandong WANG, Wuhan (CN); Xiaofen ZHENG, Wuhan (CN)

(21) Appl. No.: 18/891,988

(22) Filed: Sep. 20, 2024

(30) Foreign Application Priority Data
Aug. 15, 2024 (CN) 202411124706.9

(51) Int. Cl. H10B 43/10; H10B 41/10; H10B 41/27; H10B 41/35; H10B 43/27; H10B 43/35

(52) U.S. Cl. CPC H10B 43/10; H10B 41/10; H10B 41/27; H10B 41/35; H10B 43/27; H10B 43/35

(57) ABSTRACT

The present disclosure relates to methods, devices, and systems for managing contact structures in semiconductor devices. An example semiconductor device includes a first stack of conductive layers and isolating layers alternating with each other along a first direction, and a second stack of dielectric layers and isolating layers alternating with each other along the first direction. The semiconductor device further includes a first contact structure and a second contact structure both extending in the second stack. The first contact structure is coupled to a first conductive layer in the first stack through a first connection layer in the second stack. The second contact structure is coupled to a second conductive layer in the first stack through a second connection layer in the second stack. The first contact structure extends through the second connection layer.

### CROSS-REFERENCE TO RELATED APPLICATIONS

This application claims priority to Chinese Patent Application No. 202411124706.9, filed on Aug. 15, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first stack of conductive layers and isolating layers alternating with each other along a first direction and a second stack of dielectric layers and isolating layers alternating with each other along the first direction. The second stack is adjacent to the first stack along a second direction perpendicular to the first direction. The semiconductor device further includes a first contact structure extending in the second stack, and a second contact structure extending in the second stack. The first contact structure is coupled to a first conductive layer in the first stack through a first connection layer in the second stack. The second contact structure is coupled to a second conductive layer in the first stack through a second connection layer in the second stack. The first contact structure extends through the second connection layer.

In some implementations, the first contact structure extends through a first portion of the second stack to reach the first connection layer, and the second contact structure extends through a second portion of the second stack to reach the second connection layer. The second stack includes a surface layer including an isolating material. The second connection layer is closer to the surface layer than the first connection layer along the first direction.

In some implementations, the first connection layer has a circle shape in a plan view perpendicular to the first direction, and the second connection layer has a ring shape in the plan view.

In some implementations, the first connection layer is separated from the second connection layer by one or more alternative dielectric layers and isolating layers of the second stack.

In some implementations, the second connection layer at least partially overlaps with the first connection layer in a plan view perpendicular to the first direction.

In some implementations, a size of the first contact structure at a surface layer of the second stack is greater than a size of the second contact structure at the surface layer.

In some implementations, a diameter of the first contact structure at a surface layer of the second stack is greater than a diameter of the second contact structure at the surface layer.

In some implementations, the second connection layer includes a first portion and a second portion that is closer to the first contact structure than the first portion. A thickness of the first portion along the first direction is smaller than a thickness of the second portion along the first direction.

In some implementations, the second contact structure is coupled to the second portion of the second connection layer.

In some implementations, the semiconductor device further includes a third contact structure extending in the second stack. The third contact structure is coupled to a third conductive layer in the first stack through a third connection layer in the second stack. The third connection layer is between the first connection layer and the second connection layer along the first direction. The first contact structure extends through the third connection layer.

In some implementations, the second connection layer includes a first outer surface in contact with a first corresponding dielectric layer of the second stack, and the third connection layer includes a second outer surface in contact with a second corresponding dielectric layer of the second stack. The first outer surface of the second connection layer is closer to the first contact structure than the second outer surface of the third connection layer.

In some implementations, the second connection layer includes an inner surface spaced from the first contact structure by a first isolating structure made of an isolating material, and the third connection layer includes an inner surface spaced from the first contact structure by a second isolating structure made of the isolating material. The first isolating structure and the second isolating structure have a substantially same thickness along a third direction perpendicular to the first direction and the second direction.

In some implementations, the semiconductor device further includes a first isolating structure between the first contact structure and the second connection layer along a third direction perpendicular to the first direction and the second direction, and a second isolating structure between the first contact structure and the third connection layer along the third direction. A thickness of the first isolating structure along the third direction is greater than a thickness of the second isolating structure along the third direction.

In some implementations, the third contact structure extends through the first isolating structure. The third contact structure is separated from the second contact structure by at least part of the first isolating structure.

In some implementations, the first contact structure includes a body and an outer layer surrounding the body. The body includes a first dielectric material, the outer layer and the first connection layer include a conductive material. The first contact structure is surrounded by a contact spacer that includes a second dielectric material.

Another aspect of the present disclosure features a semiconductor device. The semiconductor device includes a first stack of conductive layers and isolating layers alternating with each other along a first direction and a second stack of dielectric layers and isolating layers alternating with each other along the first direction. The second stack is adjacent to the first stack along a second direction perpendicular to the first direction. The semiconductor device further includes a first contact structure extending in the second stack, and a second contact structure extending in the second stack. The first contact structure is coupled to a first conductive layer in the first stack. The second contact structure is coupled to a second conductive layer. A size of the second contact structure at a surface layer of the second stack is smaller than a size of the first contact structure at the surface layer of the second stack.

In some implementations, one or more first contact structures are arranged in a row along a third direction perpendicular to the first direction and the second direction. The first contact structure and the second contact structure are arranged along a fourth direction perpendicular to the first direction and different from the third direction.

In some implementations, the semiconductor structure further includes a first gate line slit structure and a second gate line slit structure both extending along the third direction. The first stack and the second stack are arranged between the first gate line slit structure and the second gate line slit structure. More than one row of the first contact structures are arranged in the second direction between the first gate line slit structure and the second gate line slit structure.

In some implementations, the first contact structure is coupled to the first conductive layer through a first connection layer in the second stack, and the second contact structure is coupled to the second conductive layer through a second connection layer in the second stack. The second connection layer at least partially overlaps with the first connection layer in a plan view perpendicular to the first direction.

In some implementations, the first contact structure extends through the second connection layer along the first direction. At least one second contact structure is coupled to the second connection layer.

Another aspect of the present disclosure features a method of forming a semiconductor device. The method includes forming a first stack of conductive layers and isolating layers alternating with each other along a first direction, and forming a second stack of dielectric layers and isolating layers alternating with each other along the first direction. The second stack is adjacent to the first stack along a second direction perpendicular to the first direction. The method further includes forming a first contact structure in the second stack, and forming a second contact structure in the second stack. The first contact structure reaches a first connection layer in the second stack. The first connection layer is coupled to a first conductive layer in the first stack. The second contact structure reaches a second connection layer in the second stack. The second connection layer is coupled to a second conductive layer in the first stack. The first contact structure extends through the second connection layer.

In some implementations, forming the first contact structure in the second stack includes etching a first portion of the second stack to a first dielectric layer to form a first hole structure along the first direction, removing the first dielectric layer and forming a first metal layer, extending the first hole structure in the second stack along the first direction by etching the first metal layer to further etch a second portion of the second stack to a second dielectric layer, removing the second dielectric layer and forming a second metal layer as the first connection layer, and depositing one or more conductive layers in the first hole structure to be in contact with the first connection layer.

In some implementations, etching the first metal layer includes etching the first metal layer to be away from a bottom of the first hole structure along a third direction perpendicular to the first direction and the second direction. The method further includes forming an isolating structure in the bottom of the first hole structure to be in contact with the etched first metal layer, and etching the isolating structure to extend the first hole structure along the first direction.

In some implementations, forming the second contact structure in the second stack includes etching a third portion of the second stack to reach the first metal layer to form a second hole structure that is spaced from the first hole structure along the second direction, and depositing the one or more conductive layers in the second hole structure to be in contact with the first metal layer as the second connection layer.

The details of one or more implementations of the subject matter of this present disclosure are set forth in the accompanying drawings and the description below. Other features, aspects, and advantages of the subject; matter will become apparent from the description, the drawings, and the claims.

### BRIEF DESCRIPTION OF DRAWINGS

FIGS. 1A-1B illustrate an example semiconductor device.

FIGS. 2A-2B illustrate cross-sectional views of a semiconductor device.

FIGS. 3A-3M illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for memory devices with a higher density, a memory device (e.g., a 3D NAND flash memory) can be formed to have a large number of layers and a larger number of word lines. Contact structures can be configured to connect conductive layers (e.g., used as word lines) to a control circuit. The design and fabrication of the contact structures can have a substantial effect on the chip size and the manufacturing cost of the memory device.

In some cases, conductive layers are connected to the control circuit using contact structures of the same type (e.g., first contact structures). For example, each first contact structure can include a body made of a first conductive material and an outer layer made of a second conductive material surrounding the body. However, as the number of conductive layers in the memory device increases, a larger number of the first contact structures may be needed to connect the conductive layers to the control circuit, and the size (e.g., diameter) and depth of the first contact structure may increase. As such, the first contact structures may take up a large area, which may decrease the memory cell density of the memory device.

The present disclosure provides techniques to reduce the area taken by contact structures in the memory device. In some implementations, different types of contact structure can be used to connect conductive layers to the control circuit. For example, some of the conductive layers are connected using first contact structures, while some of the conductive layers are connected using second contact structures. The second contact structures can have a smaller size than the first contact structures, and can be distrusted among the first contact structures. The bottom of each of the first contact structures and the second contact structures is coupled to a connection layer. In some implementations, a second contact structure can overlap with a first connection layer coupled to a first contact structure in plan view perpendicular a vertical direction. The first contact structure can extend through a second connection layer coupled to the second contact structure.

Techniques of the present disclosure can provide one or more of the following technical advantages and/or benefits. For example, by using both the first contact structures and the second contact structures, a smaller area is needed to arrange the contact structures as compared to the scenario where only first contact structures are used. As such, the memory cell density of the memory device can be increased, and the chip size of the memory device can be reduced. For another example, the described techniques can be implemented with simple process steps, and the process window is large based on existing techniques to fabricate the memory device. In some implementations, different or more technical advantages may be achieved.

The described techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

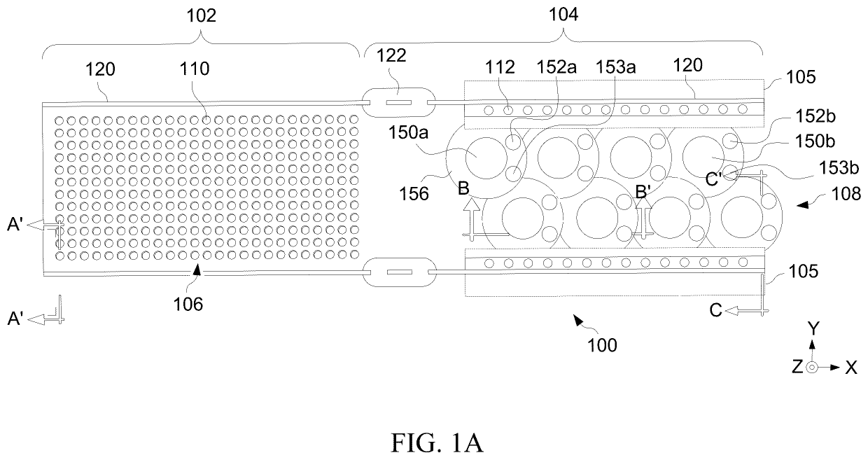

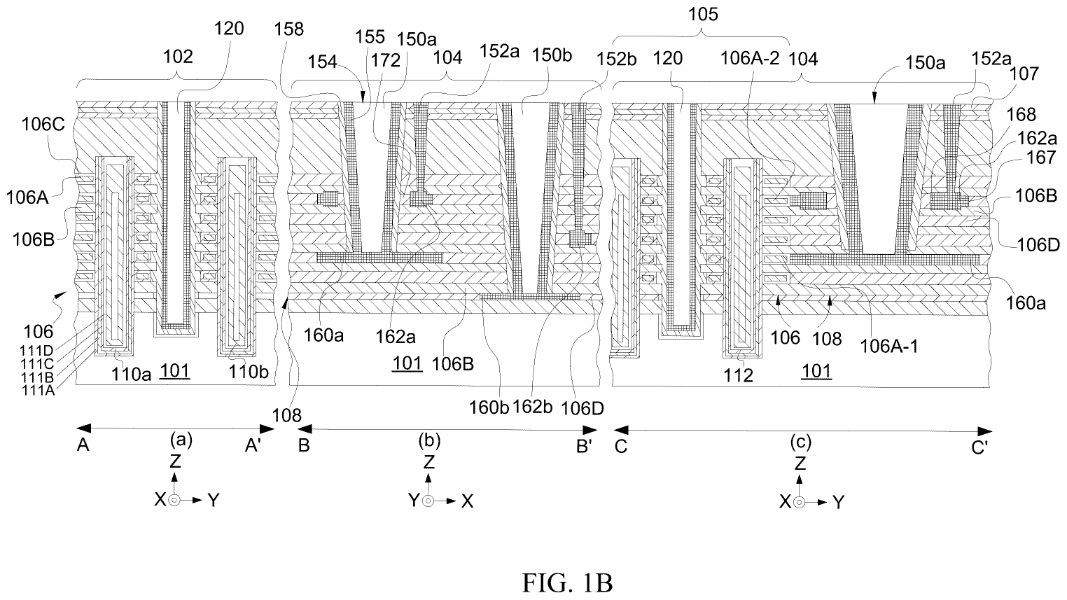

It is noted that X, Y, and Z axes (also referred to as X, Y, and Z directions) are included in FIGS. 1A-3B to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a first stack 106 of alternating conductive layers and isolating layers (e.g., conductive layers 106A and isolating layers 106B as shown in FIG. 1B). In some implementations, a part of the first stack 106 can be in the array region 102, and another part of the first stack 106 can be in the connection region 104. For example, a part of the first stack 106 can be in a tunnel region 105 of the connection region 104. The semiconductor device 100 further includes a second stack 108 of alternating dielectric layers and isolating layers (e.g., dielectric layers 106D and isolating layers 106B as shown in FIG. 1B). In some implementations, the second stack 108 can be in the connection region 104. The first stack 106 is connected to the second stack 108.

The semiconductor device 100 can include an array of channel structures 110 extending through the first stack 106 in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the first stack 106 in the tunnel region 105. In some implementations, the dummy channel structures 112 can be in one or more dummy regions or peripheral regions (not shown in FIG. 1A).

The semiconductor device 100 can include one or more gate line slit structures 120. Each gate line slit structure 120 can extend along the X direction. The gate line slit structure 120 can extend into both the array region 102 and the connection region 104. Regions around the gate line slit structures 120 in the connection region 104 can be used as the tunnel region 105. In some implementations, the gate line slit structures 120 can divide an array region 102 into multiple memory blocks. For example, a memory block (as shown in FIG. 1A) can be arranged between two memory blocks (not shown in FIG. 1A) along a second horizontal direction (e.g., the Y direction) in the array region 102, where the gate line slit structures 120 are boundaries that separate adjacent memory blocks. In some implementations, the gate line slit structure 120 can function as a common source contact for the channel structures 110 in the array region 102. As shown in FIG. 1A, each gate line slit structure 120 can include multiple segments separated and spaced by separating structures 122. The separating structures 122 can eliminate or reduce stress built in the gate line slit structure 120 during the manufacturing process, thereby preventing the gate line slit structure 120 from bending or cracking. In some implementations, a separating structure 122 can separate a first portion of a gate line slit structure 120 that is in the array region 120 from a second portion of the gate line slit structure 120 that is in the connection region 104, so that different etching processes can be implemented for different portions of the gate line slit structure 120. For example, a first etching process can be implemented to etch away dielectric layers 106D in the array region 102 through the first portion of the gate line slit structure 120. A second etching process can be implemented to etch away dielectric layers 106D in a tunnel region 105 through the second portion of the gate line slit structure 120. Conductive layers 106A can be formed in replace of the dielectric layers 106D in the array region 104 and in the tunnel region 105.

In some implementations (not shown in FIG. 1A), the gate line slit structure 120 can further include one or more segments extending along the second horizontal direction. In some implementations, the gate line slit structure 120 can include multiple segments connected in an H shape or a T shape. In some implementations, the segments of each gate line slit structure 120 can have similar or a same width (e.g., measured along the Y direction). In some other implementations, the segments of each gate line slit structure 120 can have different widths (e.g., measured along the Y direction). In some implementations, along the Y direction, a width of the segment of the gate line slit structure 120 in the connection region 104 is larger than a width of the segment of the gate line slit structure 120 in the array region 102. For example, the width of the segment in the connection region 104 can be approximately 1.5 to 2 times that of the segment in the array region 102.

The semiconductor device 100 can include contact structures in the connection region 104. A contact structure can be configured to connect a corresponding one of the conductive layers of the first stack 106 to a control circuit. In some implementations, the semiconductor device 100 can include different types of contact structures, such as first contact structures 150a, 150b (collectively as 150), second contact structures 152a, 152b (collectively as 152). The first contact structures and the second contact structures have different sizes at a surface layer of the second stack 108 (e.g., the surface layer 107 as shown in FIG. 1B). In some implementations, a size of the first contact structure 150 is greater than a size of the second contact structure 152. In some implementations, a diameter of the first contact structure 150 is greater than a diameter of the second contact structure 152 at the surface layer of the second stack 108. For example, the diameter of the first contact structure 150 ranges from 300 nm to 2 μm, e.g., 500 nm, and the diameter of the second contact structures 152 ranges from 300-400 nm, e.g., about 300 nm. In some implementations, the semiconductor device 100 can further include third contact structures 153a, 153b (collectively 153). The third contact structures 153 can have same or similar sizes as the second contact structures 152.

Each of the first contact structures 150, the second contact structures 152, and third contact structures 153 are coupled to a connection layer 156 having a conductive material. The connection layers 156 are in the connection region 104 below the surface layer of the second stack 108. In some implementations, the connection layer 156 coupled to the first contact structure 150a, the connection layer 156 coupled to the second contact structure 152a, and the connection layer 156 coupled to the third contact structure 153a overlap, or partially overlap with each other in a plan view perpendicular to a vertical direction (e.g., the Z direction). Further, the first contact structure 150a extends along the vertical direction through the connection layers 156 coupled to the second contact structure 152a and the third contact structure 153a. In some implementations, the second contact structure 152a overlaps with the connection layer 156 coupled to the first contact structures 150a in the plan view. The connection layer 156 coupled to the second contact structures 152a is closer to the surface layer of the second stack 108 than the connection layer 156 that are coupled to the first contact structures 150a.

Similarly, the connection layer 156 coupled to the first contact structure 150b, the connection layer 156 coupled to the second contact structure 152b, and the connection layer 156 coupled to the third contact structure 153b overlap, or partially overlap with each other in the plan view. The first contact structure 150b extends along the vertical direction through the connection layers 156 coupled to the second contact structure 152b and the third contact structure 153b.

Each connection layer 156 is further coupled to a conductive layer 106A of the first stack 106 (e.g., the first stack 106 in the tunnel region 105). In other words, a conductive layer 106A of the first stack 106 forms connection to a control circuit through one of the contact structures 150, 152, 153. In some implementations, the semiconductor device 100 includes only first contact structures 150 and second contact structures 152. As such, half of the conductive layers 106A (e.g., the bottom half) of the first stack 106 forms connection to the control circuit through first contact structures 150, and the other half of the conductive layers 106A (e.g., the top half) form connection to the control circuit through second contact structures 152. In some implementations, the semiconductor device 100 includes first contact structures 150, second contact structures 152 and third contact structures 153. As such, a third of the conductive layers 106A (e.g., a bottom portion) of the first stack 106 form connection to the control circuit through first contact structures 150, a third of the conductive layers 106A (e.g., a middle portion) of the first stack 106 form connection to the control circuit through third contact structures 153, and a third of the conductive layers 106A (e.g., a top portion) of the first stack 106 form connection to the control circuit through second contact structures 152. As one example, if the first stack 106 has 360 conductive layers 106A stacked along the vertical direction, the 1^{st} to the 120^{th} conductive layers 106A (e.g., in the top portion of the first stack 106) form connection to the control circuit through second contact structures 152, the 121^{st} to the 240^{th} conductive layers 106A (e.g., in the middle portion of the first stack 106) form connection to the control circuit through third contact structures 153, and the 241 to the 360^{th} conductive layers 106A (e.g., in the bottom portion of the first stack 106) form connection to the control circuit through first contact structures 150.

In some implementations, one or more first contact structures 150 are arranged in a row along the first horizontal direction (e.g., the X direction). Each of the second contact structures 152 and each of the third contact structures 153 are arranged around a corresponding first contact structure 150. For example, a second contact structure 152a or a third contact structure 153a can each be arranged, relative to the first contact structure 150a, along a direction (e.g., Y direction) that is different from the first horizontal direction, so that the layout of contact structures in the connection region 104 can be more efficient. In some implementations, there is one row of first contact structures 150 between two gate line slit structures 120. In some implementations, there are more than one row of first contact structures 150 between two gate lines structures 120. For example, as shown in FIG. 1A, two rows of first contact structures are arranged in the connection region 104 between two gate line slit structures 120. The connection layers 156 of each first contact structure 150, each second contact structure 152, and each third contact structure 153 are coupled to a conductive layer 106A of the first stack 106 in at least one of the tunnel regions 105. It should be noted that the number of the first contact structures 150, second contact structures 152 and third contact structures 153 in FIG. 1A is for illustration only. In some implementations, the semiconductor device can include fourth contact structures, fifth contact structures having the same or similar structure as the second contact structures 152.

FIG. 1B illustrates cross-sectional views of the semiconductor device 100 along cut line AA′, BB′ and CC′ of FIG. 1A, respectively. The semiconductor device 100 includes a substrate 101, the first stack 106 of alternating conductive layers 106A and isolating layers 106B, and the second stack 108 of alternating dielectric layers 106D and isolating layers 106B. Each isolating layer 106B can have a portion between two adjacent conductive layers 106A in the first stack 106 and another portion between two adjacent dielectric layers 106D in the second stack 108. The first stack 106 and the second stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100 to expose ends of the channel structures 110. The channel structures can include multiple layers including an isolating layer 111A (e.g., a silicon oxide layer), a dielectric layer 111B (e.g., a silicon nitride layer), an isolating layer 111C (e.g., a silicon oxide layer), and a channel layer 111D (e.g., a polysilicon layer). The isolating layer 111A, the dielectric layer 111B and the isolating layer 111C at the exposed ends of the channel structure 110 can further be removed to expose the channel layer 111D. A semiconductor layer (not shown in FIG. 1B) can be deposited to be in contact with the exposed channel layers 11D of different channel structures 110 (e.g., all channel structures 110 of a memory block) to form a common source. The semiconductor device 100 can include a surface layer 107 made of an isolating material (e.g., oxide).

The first stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in a vertical direction (e.g., Z direction) perpendicular to the second horizontal direction. The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the first stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations, as illustrated in FIG. 1B, the first stack 106 includes liner layers 106C. A liner layer 106C can cover part or all sides of a corresponding conductive layer 106A and be between the conductive layer 106A and two isolating layers 106B adjacent to the corresponding conductive layer 106A. The liner layer 106C can include a high-K dielectric material (e.g., Al₂O₃). In some examples, the conductive layer 106A includes a (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material.

As shown in FIG. 1B, the first stack 106 can include channel structures 110 extending along the vertical direction. For example, the first stack can include two memory blocks separated by the gate line slit structure 102. The first memory block can include channel structures 110a, and the second memory block can include channel structures 110b.

The second stack 108 include dielectric layers 106D and isolating layers 106B alternating with each other along the vertical direction (e.g., Z direction). The second stack 108 can be connected to the first stack 106. The isolating layers 106B can extend into both the first stack 106 and the second stack 108 along the second horizontal direction (e.g., Y direction) in the connection region 104. A dielectric layer 106D in the second stack 108 can extend to and be in contact with a corresponding conductive layer 106A (or a liner layer 106C surrounding the corresponding conductive layer 106A) in the first stack 106. To fabricate the first stack 106 and the second stack 108, a series of alternating dielectric layers 106D and isolating layers 106B can be first formed. Then, dielectric layers 106D in a region of the first stack 106 can be etched away, e.g., through an opening formed in the position of the gate line slit structure 120, while dielectric layers 106D in the second stack 108 remain unchanged. Then, the liner layers 106C and the conductive layers 106A can be formed in replace of the dielectric layers 106D in the region of the first stack 106 to form the first stack 106.

The gate line slit structure 120 can extend through the first stack 106 along the vertical direction (e.g., the Z direction). In some implementations, as shown in FIG. 1B, the gate line slit structure 120 can extend from the surface layer 107 into the substrate 101 along the vertical direction. The dummy channel structure 112 also can extend through the first stack 106 along the vertical direction (e.g., the Z direction). In some implementations, as shown in FIG. 1B, the dummy channel structure 112 can extend into the substrate 101 along the Z direction.

The first contact structure 150a or 150b (collectively as 150) can extend through at least a portion of the second stack 108 (e.g., a set of dielectric layers 106D and isolating layers 106B of the second stack 108) along the vertical direction. As shown in FIG. 1B, the first contact structure 150 can include a body 154 and an outer layer 155. The first contact structure 150 is coupled to a first connection layer 160a or 160b (collectively as 160, e.g., one of the connection layers 156 of FIG. 1A). The body 154 and the outer layer 155 can extend along the Z direction, and the first connection layer 160 can extend in the X-Y plane (e.g., perpendicular to the Z direction). The first connection layer 160 can have a circle shape in the X-Y plane. The outer layer 155 can be surrounding and in contact with the body 154. The body 154 and the outer layer 155 can be connected to the first connection layer 160. The body 154 can include a first conductive material. Both the outer layer 155 and the first connection layer 160 can include a same conductive material, which can be referred to as a second conductive material and can be different from the first conductive material of the body 154. In some implementations, the first conductive material and the second conductive material can be one of a metallic material such as W, or TiN. In some implementations, the first contact structure 150 can be surrounded by a contact spacer 158, and the contact spacer 158 can include a dielectric material (e.g., silicon oxide).

The second contact structure 152a or 152b (collectively as 152) can extend through a part of the second stack 108 (e.g., a set of dielectric layers 106D and isolating layers 106B of the second stack 108) along the vertical direction. As shown in FIG. 1B, the second contact structure 152 is coupled to a second connection layer 162a or 162b (collectively as 162, e.g., one of the connection layers 156 of FIG. 1A). The second contact structure 152 and the second connection layer can include a conductive material, such as W or TiN. The second contact structure 152 can extend along the Z direction, and the second connection layer 162 can extend in the X-Y plane (e.g., perpendicular to the Z direction). The second connection layer 162 is above the first connection layer 160 along the Z direction, e.g., closer to the surface layer 107 than the first connection layer 160. The second connection layer 162 is separated from the first connection layer 160 by one or more dielectric layers 106D and isolating layers 106B of the second stack 108. In some implementations, the second connection layer 162 can have a ring shape in the X-Y plane, and the first contact structure 150 can extend through the second connection layer 162 through an opening in the center of the ring shape. In some implementations, an isolating structure 172 is between the first contact structure 150 and the second connection layer 162. The isolating structure 172 can include a dielectric material (e.g., silicon oxide) to separate the first contact structure 150 and the second connection layer 162.

The first contact structure 150 and the second contact structure 152 can be exposed from the surface layer 107 can be configured to be coupled out to an external circuit (e.g., a control circuit). The first connection layer 160 and the second connection layer 162 are each coupled to a respective conductive layer 106A of the first stack 106. For example, as shown in FIG. 1B, the first connection layer 160a is coupled to a conductive layer 106A-1. Both the first connection layer 160a and the conductive layer 106A-1 are between two adjacent isolating layers 106B along the Z direction. The second connection layer 162a is coupled to a conductive layer 106A-2. Both the second connection layer 162a and the conductive layer 106A-2 are between two adjacent isolating layers 106B along the Z direction.

In some implementations, the second connection layer 162a has a first portion 167 and a second portion 168. The first portion 167 is closer to the first contact structure 150a than the second portion 168. A thickness of the first portion 167 (e.g., measured along Z direction) is smaller than a thickness of the second portion 168. The first portion 167 of the second connection layer 162a is coupled to the conductive layer 106A-1 of the first stack 106, and the second portion 168 of the second connection layer 162 is coupled to the second contact structure 152.

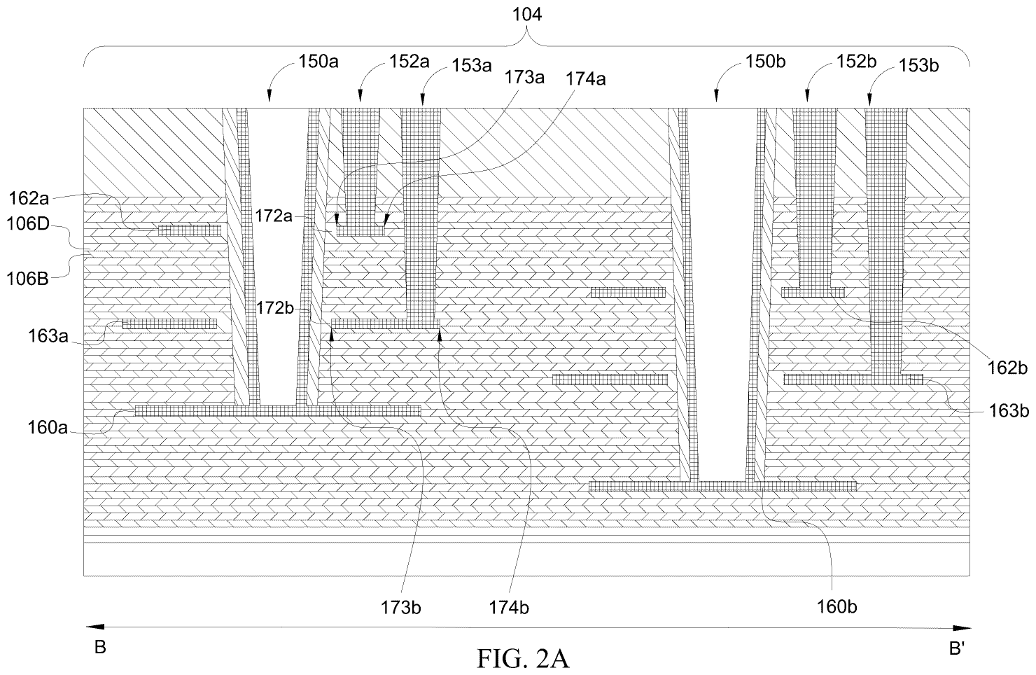

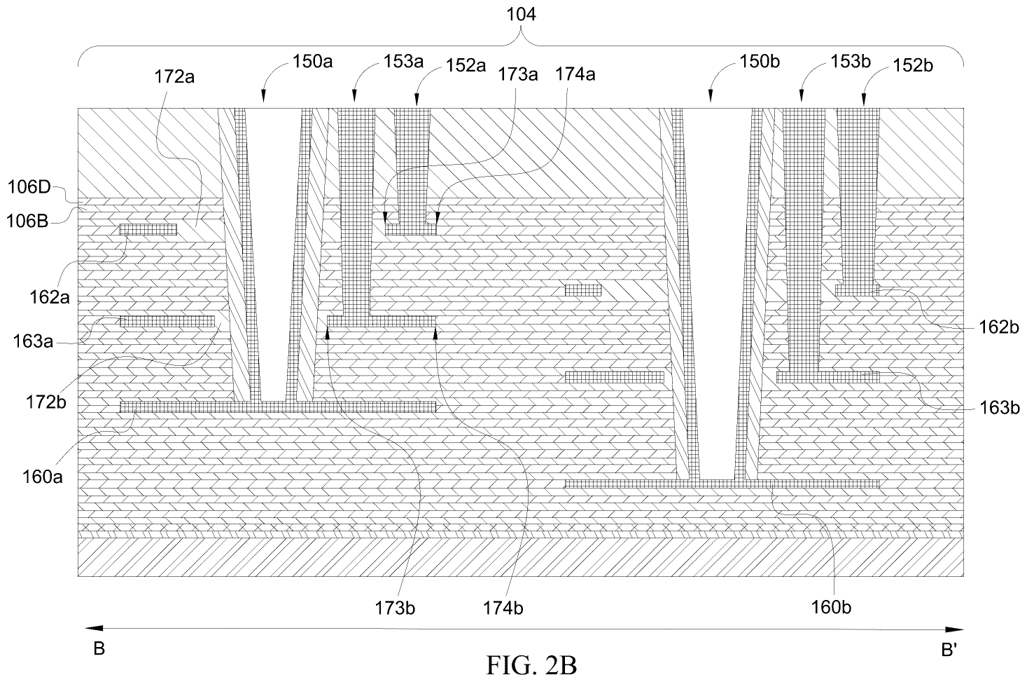

FIGS. 2A-2B illustrate cross-sectional views of a semiconductor device along cut line BB′. In some implementations, the semiconductor device includes first contact structures 150, second contact structures 152, and third contact structures 153.

Third contact structures 153a, 153b (collectively as 153) can have same or similar structures as the second contact structures 152. A third contact structure 153 can extend through a part of the second stack 108 along the vertical direction. The third contact structure 153 is coupled to a third connection layer 163a or 163b (collectively as 163). The third connection layer 163 is between the second connection layer 162 and the first connection layer 160 along the Z direction. In some implementations, the third connection layer 163 can have a ring shape in the X-Y plane, and the first contact structure 150 can extend through the third connection layer 163 through an opening in the center of the ring shape.

In some implementations, the second connection layer 162a is separated from the first contact structure 150a by the isolating structure 172a, and the third connection layer 163a is separated from the first contact structure 150a by the isolating structure 172b. Each of the second connection layer 162 and the third connection layer 163 has an inner surface 173 in contact with the isolating structure 172, and an outer surface 174 in contact with a dielectric layer 106D. The third contact structure 153 extends along the Z direction below the second connection layer 162, but the third contact structure 153 is not in contact with the second connection layer 162.

In some implementations, as shown in FIG. 2A, the isolating structures 172a and 172b have the same, or substantially same width along the X direction, so that the inner surface 173a of the second connection layer 162 and the inner surface 173b of the third connection layer 163 have the same distance to the first contact structure 150. The third connection layer 163 extends further along the X direction than the second connection layer 162, so that the outer surface 174b of the third connection layer 163 is further away from the first contact structure 150 than the outer surface 174a of the second connection layer 162. As such, the third contact structure 153 can extend along the Z direction to be in contact with the third connection layer 163 at a portion close to the outer surface 174b, without being in contact with the second connection layer 162.

In some implementations, as shown in FIG. 2B, a width of the isolating structure 172a along the X direction is greater than a width of the isolating structure 172b, so that the inner surface 173a of the second connection layer 162 is further away from the first contact structure 150 than the inner surface 173b of the third connection layer 163. In some implementations, the outer surfaces 174a of the second connection layer 162 and the outer surface 174b of the third connection layer 163 have the same distance to the first contact structure 150. As such, the third contact structure 153 can extend along the Z direction to be in contact with the third connection layer 163 at a portion close to the inner surface 173b, without being in contact with the second connection layer 162.

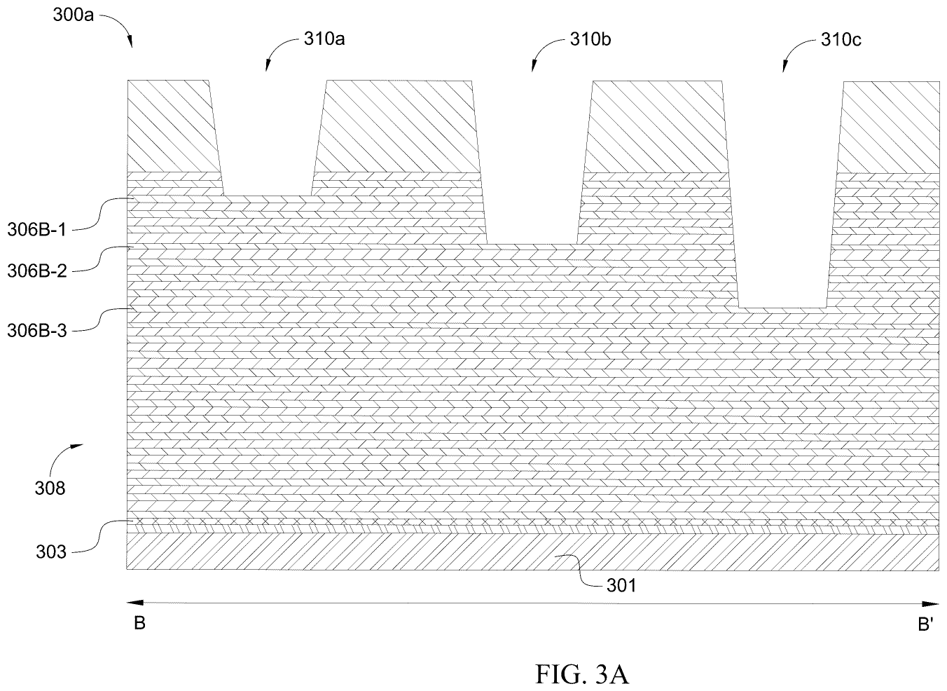

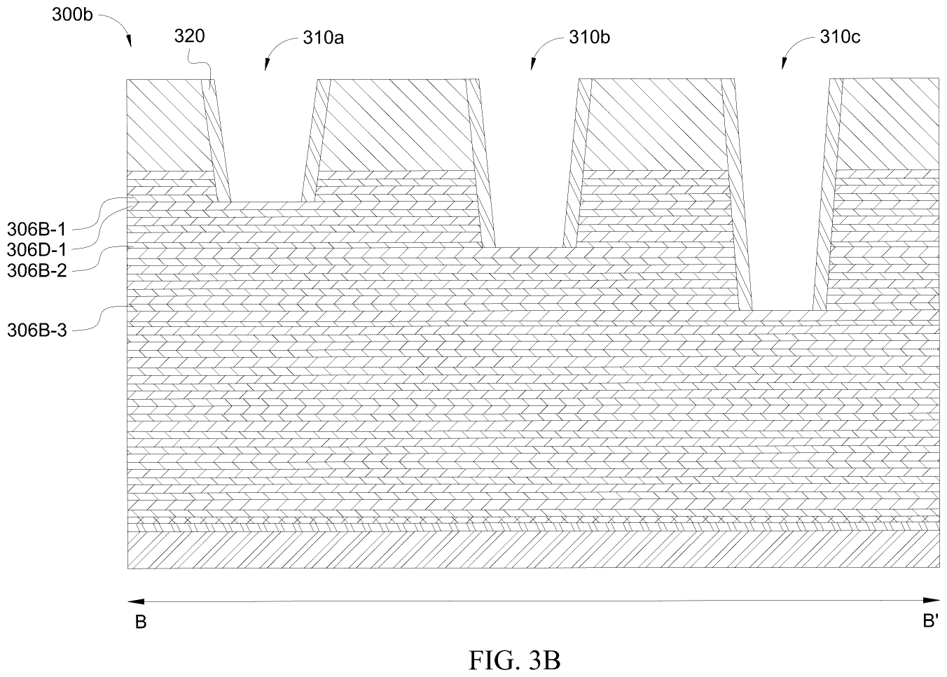

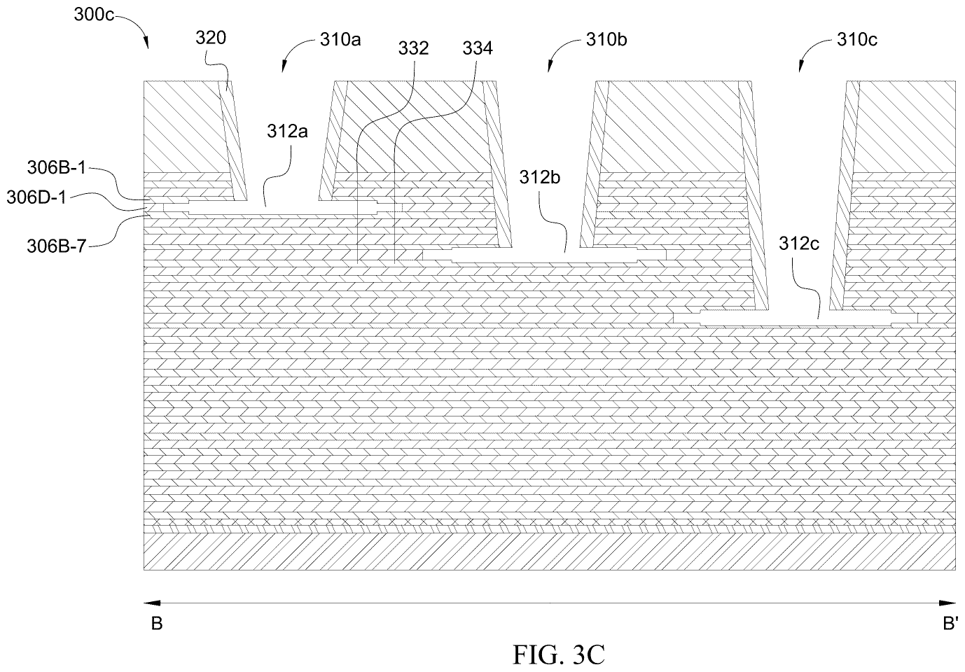

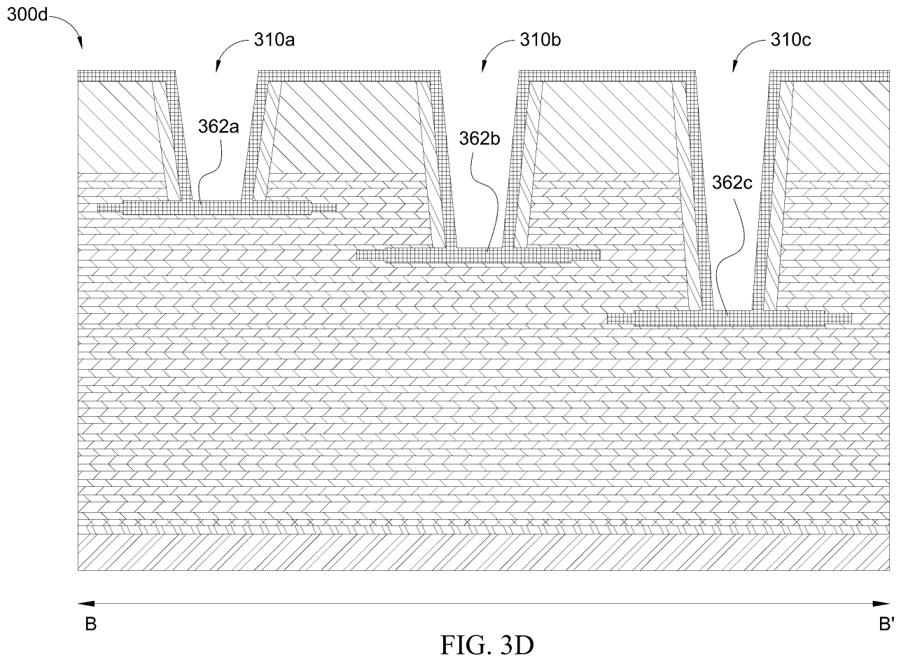

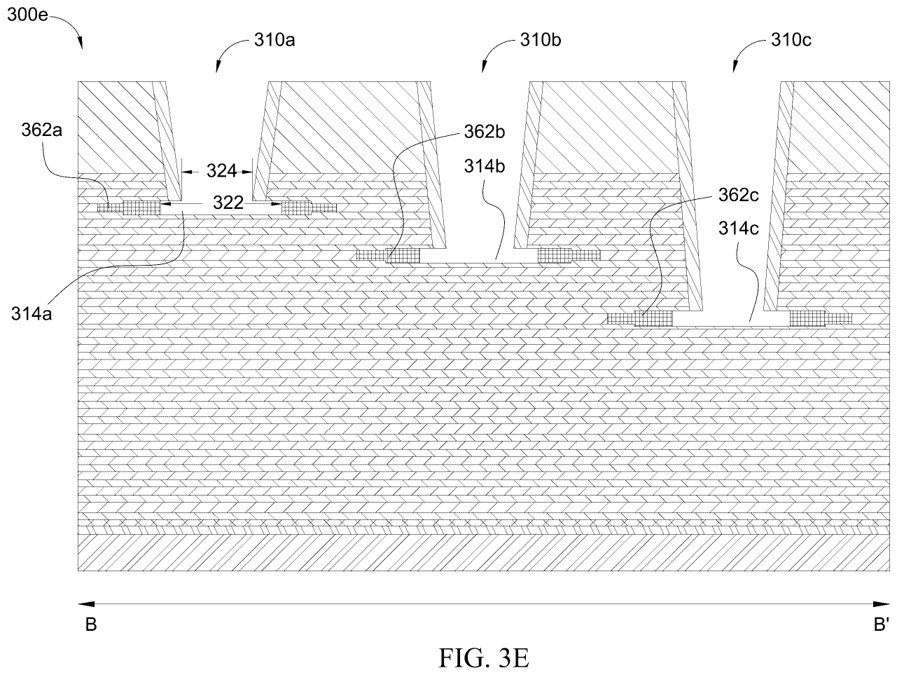

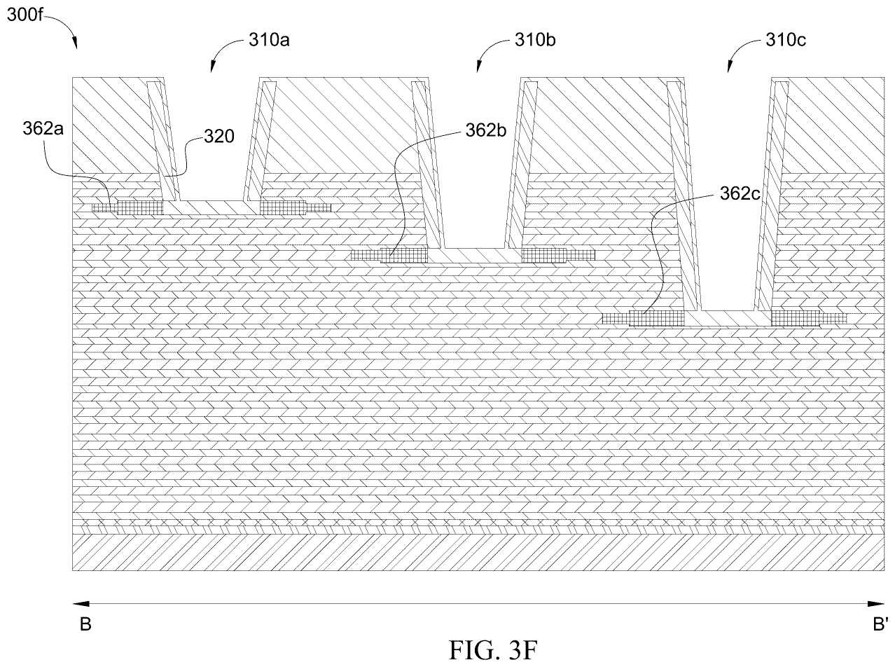

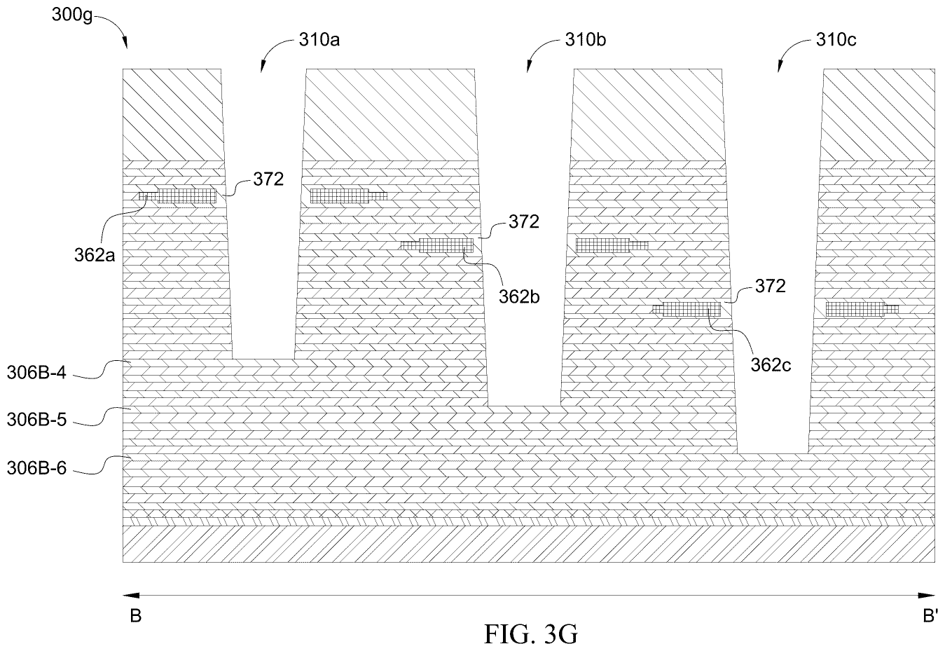

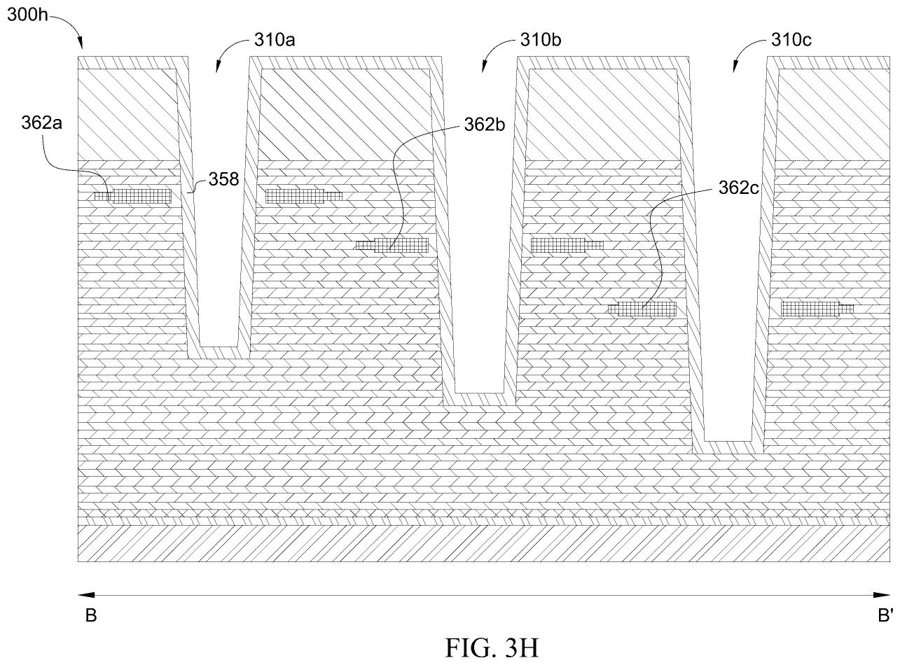

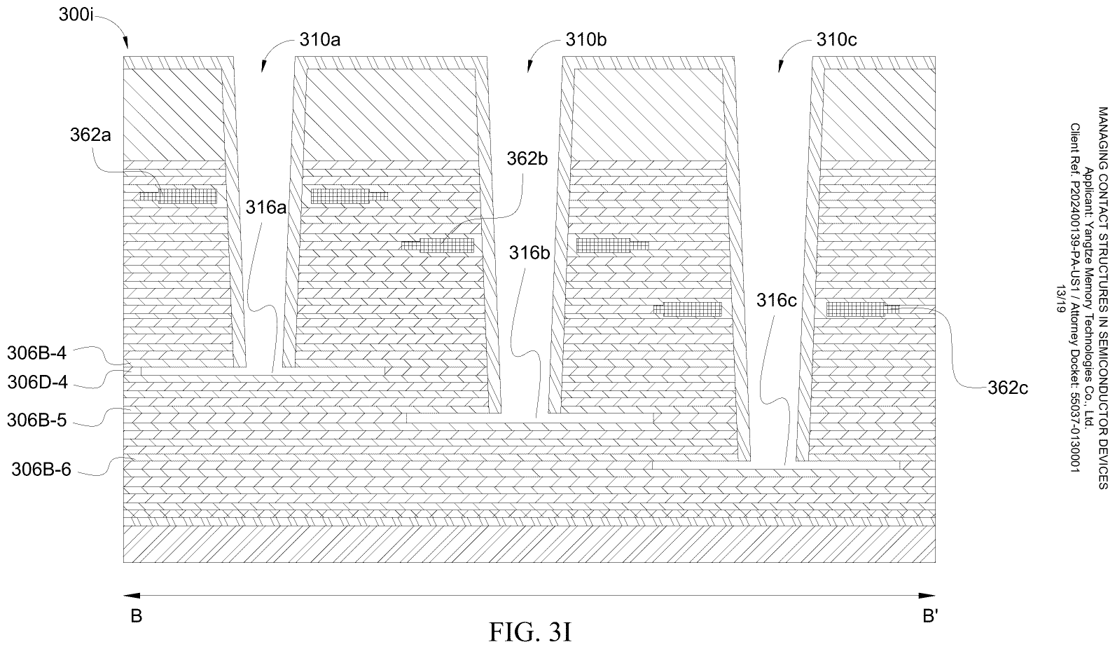

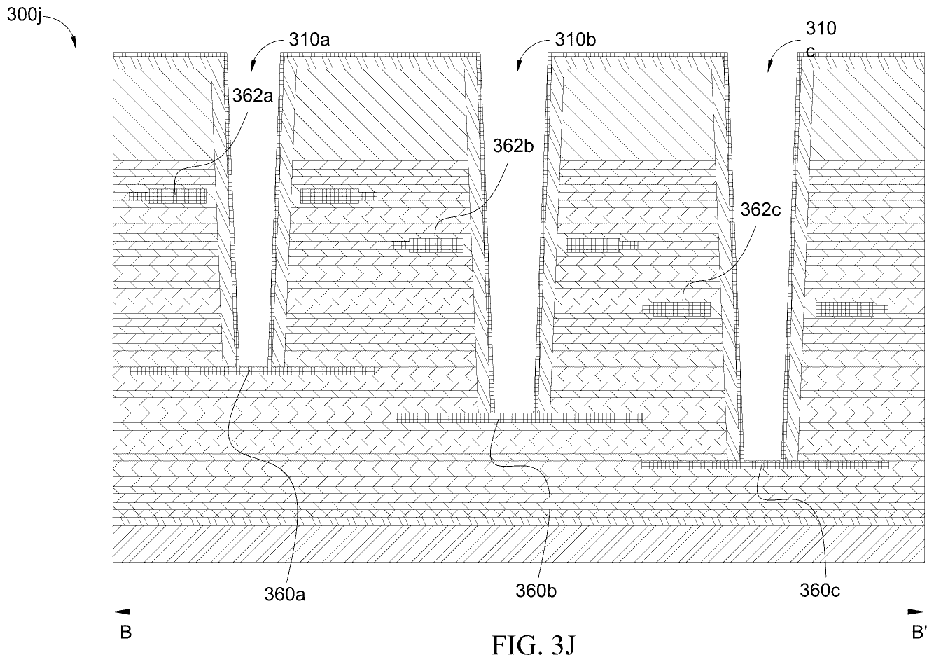

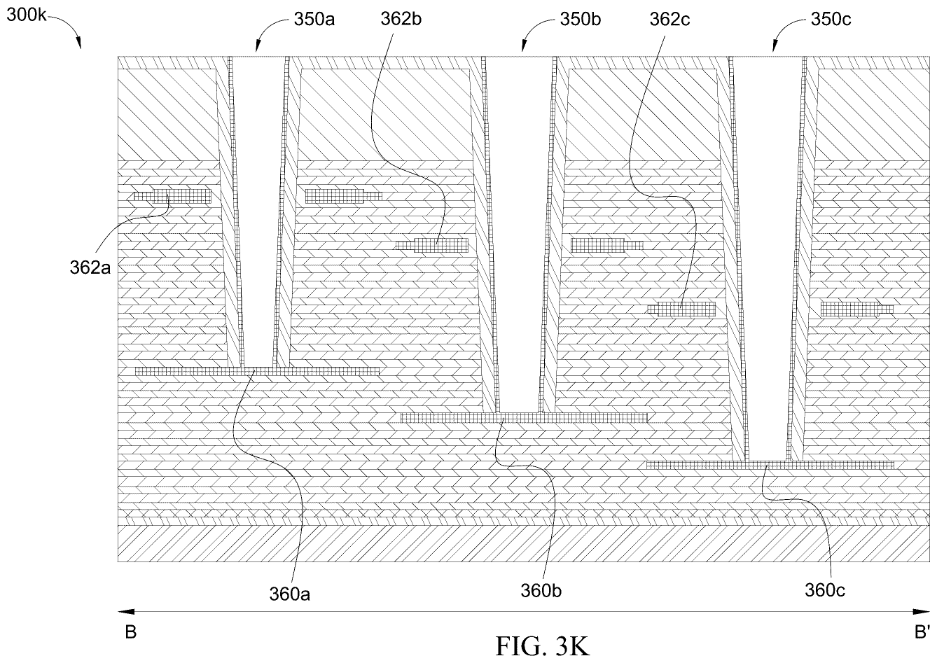

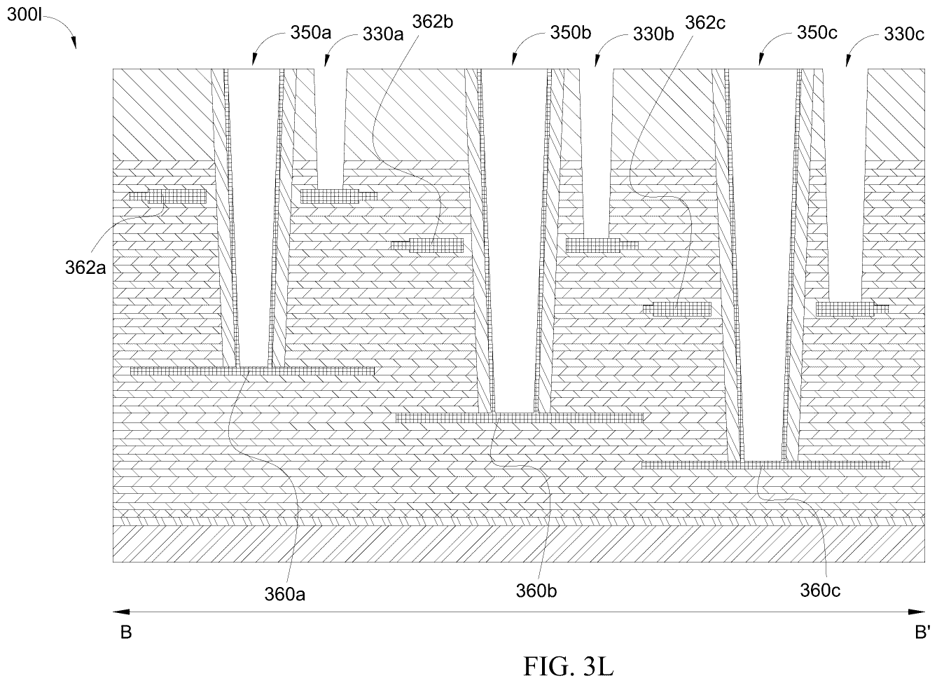

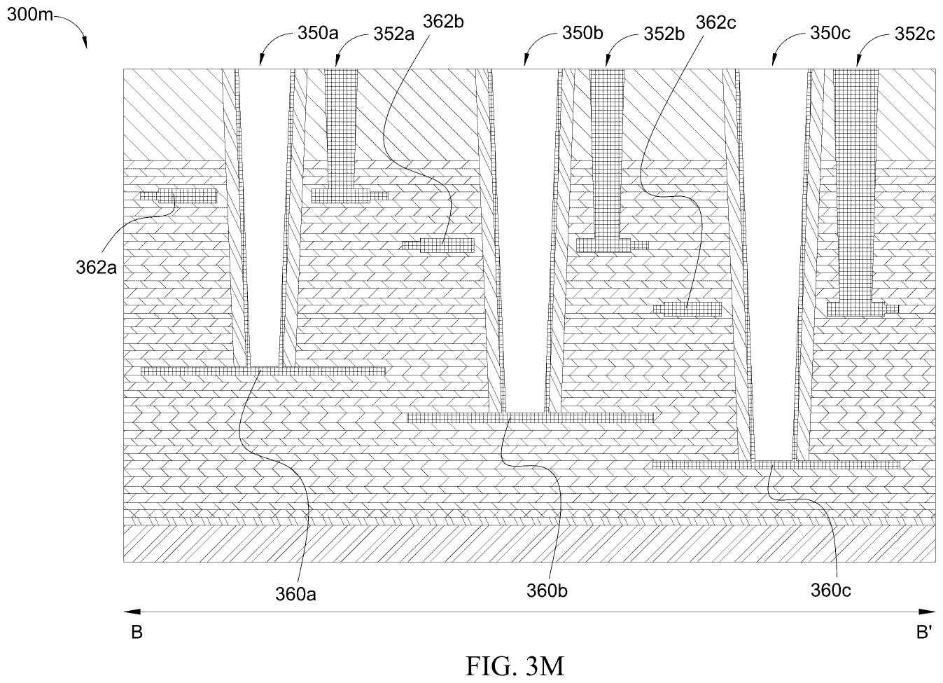

FIGS. 3A-3M illustrate an example process of fabricating a semiconductor device, such as the semiconductor device as illustrated in FIGS. 1A-2B. FIGS. 3A-3M show cross-sectional views of example semiconductor structures along the cut line BB′ of FIG. 1A at various stages of the fabrication process.

As shown in FIG. 3A, a semiconductor structure 300a is formed. The semiconductor structure 300a includes a substrate 301 and a stack 308 of alternating dielectric layers 306D and isolating layers 306B provided over the substrate 301. The dielectric layers 306D and the isolating layers 306B can alternate in the vertical direction (e.g., the Z direction). The isolating layers 306B can include dielectric material, such as silicon oxide, silicon nitride, silicon oxynitride, or any combination thereof. In some implementations, the dielectric layers 306D can include a dielectric material different from the dielectric material of the isolating layers 306B. For example, the isolating layers 306B can include silicon oxide, and the dielectric layers 306D can include silicon nitride. In some implementations, the semiconductor structure 300a can further include a polysilicon layer 303 between the stack 308 and the substrate 301 along the vertical direction.

As shown in FIG. 3A, first contact holes 310a, 310b, 310c (collectively as 310) are formed through a portion of the stack 308 by an etching process. Each first contact hole 310 can extend from a top surface (e.g., a surface farther away from the substrate 301) of the semiconductor structure 300a to an isolating layer 306B of the stack 308. In some implementations, the first contact holes 310 each extends to a different isolating layer 306B of the stack 308. For example, the first contact hole 310a can extend to the M^{th} (e.g., numbered from the top surface of the stack 308 to the substrate 301) isolating layer 306B-1 of the stack 308; the first contact hole 310b can extend to (M+k)^{th} isolating layer 306B-2 of the stack 308; and the first contact hole 310c can extend to (M+2k)^{th} isolating layer 306B-3 of the stack 308, where M and k are integers.

As shown in a semiconductor structure 300b of FIG. 3B, a contact spacer 320 can be deposited on an inner surface of each first contact hole 310. The contact spacer 320 can include a dielectric material, such as silicon oxide. The contact spacer 320 can be deposited using an atomic layer deposition (ALD) method or a chemical vapor deposition (CVD) method. In some implementations, the contact spacer 320 is first deposited on both the inner surface and the bottom surface of the first contact hole 310a. Then, by an etching process, the contact spacer 320 on the bottom surface of the first contact holes 310a is removed, and the first contact hole 310a can be deepened to reach a dielectric layer 306D-1 below the isolating layer 306B-1. In some implementations, the contact spacer 320 can protect the dielectric layers 306D exposed by the first contact holes 310 from being affected by subsequent etching processes.

As shown in a semiconductor structure 300c of FIG. 3C, a space 312a can be formed at the bottom of the first contact hole 310a by removing a portion of the dielectric layer 306D-1. The portion of the dielectric layer 306D-1 can be removed by an etching process, such as wet etching. In some implementations, the etching process can cause the space 312a to expand at a position closer to the first contact hole 310a, such that a size of the space 312a along the Z direction at a position 332 is larger than a size of the space 312a along the Z direction at a position 334. For example, a first etchant can be used during a first time period of the etching process. The first etchant can etch off the sacrificial layer 306D-1 and the two isolating layers 306B-1 and 306B-7 adjacent to the sacrificial layer 306D-1. Thus, a first portion of the sacrificial layer 306D-1 and portions of the isolating layers 306B-1 and 306B-7 can be etched off during the first time period of the etching process. A second etchant can be used during a second time period of the etching process. The second etchant can etch off the sacrificial layer 306D-1 and has less or no effect on the isolating layers 306B-1 and 306B-7. Thus, a second portion of the sacrificial layer 306D-1 can be etched off during the second time period of the etching process.

Similarly, spaces 312b, 312c can be formed at the bottom of the first contact hole 310b and the first contact hole 310c.

As shown in a semiconductor structure 300d of FIG. 3D, metal layers 362 can be formed by filling a metallic material (e.g., W) into the spaces 312. In some implementations, when depositing the metallic material in the spaces 312, the metallic material is also deposited on an inner surface of the first contact holes 310 and on a top surface of the semiconductor structure 300d.

FIG. 3E illustrates a semiconductor structure 300e, which can be formed by removing the metallic material on the inner surface of the first contact holes 310 and on the top surface of the semiconductor structure 300d. A portion of the metal layer 362a is etched away from the bottom of the first contact hole 310a along the X direction, to create a space 314a. In some implementations, a length 322 of the space 314a along X direction is larger than a length 324 of the bottom of the first contact hole 310. Similarly, spaces 314b, 314c can be formed under the first contact hole 310b and the first contact hole 310c.

FIG. 3F illustrates a semiconductor structure 300f, which can be formed by filling the spaces 314 with a dielectric material (e.g., silicon oxide). In some implementations, the dielectric material can be deposited into the spaces 314 using an ALD method.

FIG. 3G illustrates a semiconductor structure 300g, which can be formed by extending the first contact holes 310 by an etching process. In some implementations, the first contact holes 310a, 310b, 310c are extended by etching away the same amount of isolating layers 306B and dielectric layers 306D of the stack 308. For example, the first contact hole 310a can extend to the (M+j)^{th} isolating layer 306B-4 of the stack 308; the first contact hole 310b can extend to (M+k+j)^{th} isolating layer 306B-5 of the stack 308; and the first contact hole 310a can extend to (M+2k+j)^{th} isolating layer 306B-6 of the stack 308, where M, k and j are integers.

In some implementations, the contact spacer 320 are also removed during the etching process. A portion of the dielectric material that were filled in spaces 314 are retained during the etching process to form isolating structures 372 adjacent to the remaining metal layers 362.

FIG. 3H illustrates a semiconductor structure 300h, which can be formed by depositing a contact spacer 358 on the inner surface of the extended first contact holes 310.

As shown in a semiconductor structure 300i of FIG. 3I, the first contact hole 310a can be deepened to reach a dielectric layer 306D-4 below the isolating layer 306B-4. A space 316a can be formed at the bottom of the first contact hole 310a by removing a portion of the dielectric layer 306D-4. The portion of the dielectric layer 306D-4 can be removed by an etching process, such as wet etching. Similarly, spaces 316b, 316c can be formed at the bottom of the first contact hole 310b and the first contact hole 310c.

As shown in a semiconductor structure 300j of FIG. 3J, metal layers 360 can be formed by filling a metallic material (e.g., W) into the spaces 316. Further, the metallic material is deposited on the inner surface of the first contact holes 310 to be in contact with metal layers 360.

FIG. 3K illustrates a semiconductor structure 300k, which can be formed by filling the first contact holes 310 with a conductive material (e.g., W or TiN). The conductive material can be in contact with the metal layers 360. In some implementations, excess metallic material and conductive material on the top surface of the semiconductor structure 300k can be removed by performing a planarization process, such as chemical mechanical polishing (CMP). As shown in FIG. 3J, first contact structures 350 are formed. Each first contact structure 350 is coupled to a metal layer 360, which can serve as a first connection layer.

FIG. 3L illustrates a semiconductor structure 300l, which can be formed by forming second contact holes 330a, 330b, 330c (collectively as 330) through a portion of the stack 308 by an etching process (e.g., photoetching). The second contact holes 330 can extend from a top surface of the semiconductor structure 300l along the Z direction to reach a corresponding metal layer 362. For example, the second contact hole 330a reaches the metal layer 362a, the second contact hole 330b reaches the metal layer 362b, and the second contact hole 330c reaches the metal layer 362c.

FIG. 3M illustrates a semiconductor structure 300m, which can be formed by filling the second contact holes 330 with a metallic material (e.g., W) to be in contact with the metal layers 362. In some implementations, excess metallic material on the top surface of the semiconductor structure 300m are removed, e.g., by CMP. As shown in FIG. 3M, the second contact structures 352 are formed. Each second contact structure 352 is coupled to a metal layer 362, which can serve as a second connection layer.

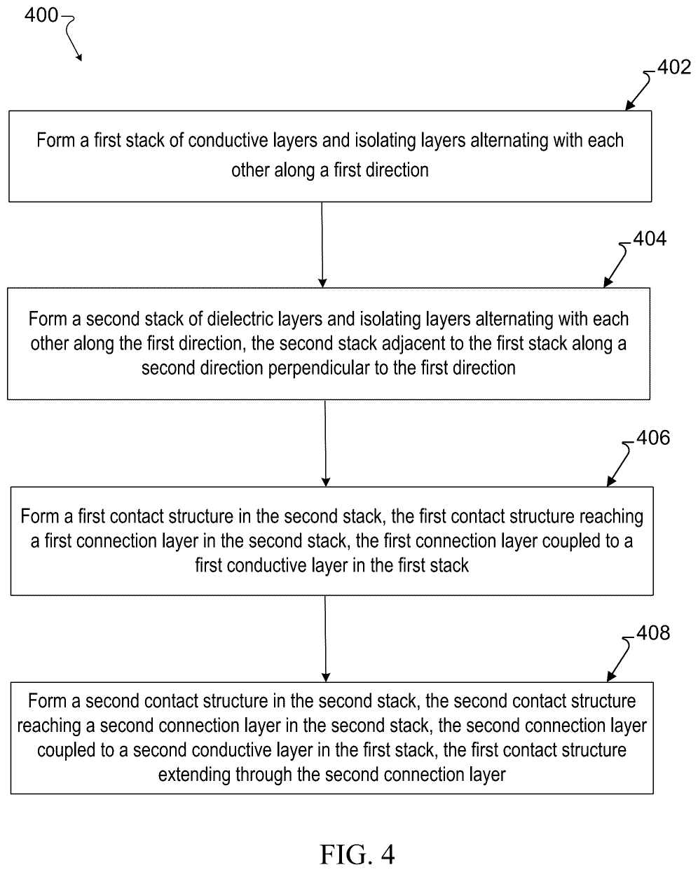

FIG. 4 illustrates a flow chart of an example process 400. The process 400 can be performed to form a semiconductor device (e.g., the semiconductor device 100 illustrated by FIGS. 1A-2B). The process 400 can be described in view of FIGS. 3A-3M. The process 400 can include one or more steps of the fabrication process of forming the semiconductor structures in FIGS. 3A-3M. It is understood that the operations shown in process 400 are not exhaustive and that other operations can be performed as well before, after, or between any of the illustrated operations. Further, some of the operations may be performed simultaneously, or in a different order than shown in FIG. 4.

At 402, a first stack (e.g., the first stack 106 of FIGS. 1A-1B) is formed. The first stack includes conductive layers (e.g., conductive layers 106A of FIGS. 1A-1B) and isolating layers (e.g., isolating layers 106B of FIGS. 1A-1B) alternating with each other along a first direction (e.g., the Z direction). The first stack can be arranged in an array region (e.g., the array region 102 of FIGS. 1A-1B) and part of a connection region (e.g., the tunnel region 105 of the connection region 104 of FIGS. 1A-1B) of the semiconductor device.

At 404, a second stack (e.g., the second stack 108 of FIGS. 1A-2B) is formed. The second stack includes dielectric layers (e.g., dielectric layers 106D of FIGS. 1A-2B) and isolating layers (e.g., isolating layers 106B of FIGS. 1A-2B) alternating with each other along the first direction. The second stack can be arranged in the connection region of the semiconductor device. The second stack is adjacent to the first stack (e.g., the first stack in the tunnel region 105) along a second direction (e.g., the Y direction) perpendicular to the first direction.

At 406, a first contact structure (e.g., the first contact structure 150a of FIGS. 1A-2B, the first contact structure 350a of FIG. 3J) is formed in the second stack. The first contact structure reaches a first connection layer (e.g., the first connection layer 160a of FIGS. 1A-2B) in the second stack. The first connection layer is coupled to a first conductive layer (e.g., the conductive layer 106A-1 of FIG. 1B) in the first stack.

In some implementations, forming the first contact structure includes etching a first portion of the second stack to a first dielectric layer (e.g., the dielectric layer 306D-1 of FIG. 3B) to form a first hole structure (e.g., the first contact hole 310a) along the first direction.

In some implementations, forming the first contact structure further includes removing the first dielectric layer and forming a first metal layer (e.g., the metal layer 362a of FIG. 3D).

In some implementations, forming the first contact structure further includes extending the first hole structure in the second stack along the first direction by etching the first metal layer to further etch a second portion of the second stack to a second dielectric layer (e.g., the dielectric layer 306D-4 of 3I), as described with reference to FIGS. 3E-3I.

In some implementations, forming the first contact structure further includes removing the second dielectric layer and forming a second metal layer (e.g., the metal layer 360a of FIG. 3J) as the first connection layer.

In some implementations, forming the first contact structure further includes depositing one or more conductive layers in the first hole structure to be in contact with the first connection layer.

At 408, a second contact structure (e.g., the second contact structure 152a of FIGS. 1A-2B, the second contact structure 352a of FIG. 3M) is formed in the second stack. The second contact structure reaches a second connection layer (e.g., the second connection layer 162a of FIGS. 1A-2B) in the second stack. The second connection layer is coupled to a second conductive layer (e.g., the conductive layer 106A-2 of FIG. 1B) in the first stack. The first contact structure extends through the second connection layer along the first direction, e.g., at the center of the ring shape of the second connection layer. In some implementations, the second contact structure is smaller in size at a surface layer of the second stack than the first contact structure.

In some implementations, forming the second contact structure includes etching the first metal layer to be away from a bottom of the first hole structure along a third direction (e.g., the X direction) perpendicular to the first direction and the second direction. The process 400 further includes forming an isolating structure (e.g., the dielectric material filled in the space 314a of FIGS. 3E-3F) in the bottom of the first hole structure to be in contact with the etched first metal layer; and etching the isolating structure to extend the first hole structure along the first direction.

In some implementations, forming the second contact structure includes etching a third portion of the second stack to reach the first metal layer to form a second hole structure (e.g., the second contact hole 330a of FIG. 3L) that is spaced from the first hole structure along the second direction. One or more conductive layers are deposited in the second hole structure to be in contact with the first metal layer, which serves as the second connection layer.

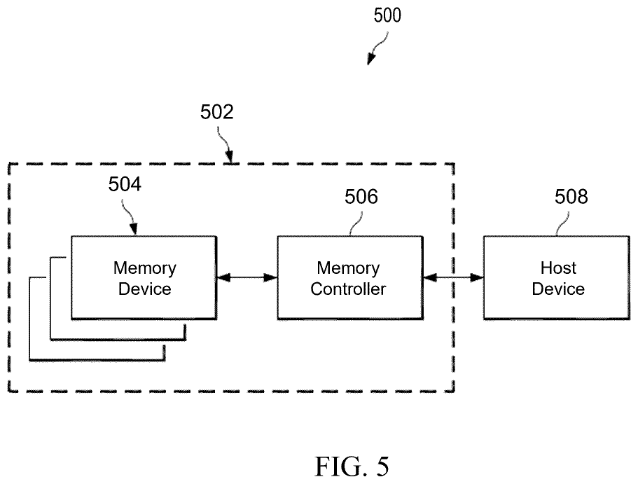

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a semiconductor device (e.g., a NAND Flash memory) as shown in FIGS. 1A-1B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card. Memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” or “approximately” can indicate a value of a given quantity that varies within, for example, 10-30% of the value (e.g., .+−.10%, .+−.20%, or .+−.30% of the value). As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction;
a second stack of dielectric layers and isolating layers alternating with each other along the first direction, wherein the second stack is adjacent to the first stack along a second direction perpendicular to the first direction;
a first contact structure extending in the second stack, wherein the first contact structure is coupled to a first conductive layer in the first stack through a first connection layer in the second stack; and
a second contact structure extending in the second stack, wherein the second contact structure is coupled to a second conductive layer in the first stack through a second connection layer in the second stack, and wherein the first contact structure extends through the second connection layer.

2. The semiconductor device of claim 1, wherein the first contact structure extends through a first portion of the second stack to reach the first connection layer, and the second contact structure extends through a second portion of the second stack to reach the second connection layer, and
wherein the second stack comprises a surface layer comprising an isolating material, and wherein the second connection layer is closer to the surface layer than the first connection layer along the first direction.

3. The semiconductor device of claim 1, wherein the first connection layer has a circle shape in a plan view perpendicular to the first direction, and the second connection layer has a ring shape in the plan view.

4. The semiconductor device of claim 1, wherein the first connection layer is separated from the second connection layer by one or more alternative dielectric layers and isolating layers of the second stack.

5. The semiconductor device of claim 1, wherein a size of the first contact structure at a surface layer of the second stack is greater than a size of the second contact structure at the surface layer.

6. The semiconductor device of claim 1, wherein the second connection layer comprises a first portion and a second portion that is closer to the first contact structure than the first portion, wherein a thickness of the first portion along the first direction is smaller than a thickness of the second portion along the first direction.

7. The semiconductor device of claim 6, wherein the second contact structure is coupled to the second portion of the second connection layer.

8. The semiconductor device of claim 1, further comprising:
a third contact structure extending in the second stack, wherein the third contact structure is coupled to a third conductive layer in the first stack through a third connection layer in the second stack,
wherein the third connection layer is between the first connection layer and the second connection layer along the first direction, and
wherein the first contact structure extends through the third connection layer.

9. The semiconductor device of claim 8, wherein the second connection layer comprises a first outer surface in contact with a first corresponding dielectric layer of the second stack, and the third connection layer comprises a second outer surface in contact with a second corresponding dielectric layer of the second stack, and
wherein the first outer surface of the second connection layer is closer to the first contact structure than the second outer surface of the third connection layer.

10. The semiconductor device of claim 9, wherein the second connection layer comprises an inner surface spaced from the first contact structure by a first isolating structure made of an isolating material, and the third connection layer comprises an inner surface spaced from the first contact structure by a second isolating structure made of the isolating material, and
wherein the first isolating structure and the second isolating structure have a substantially same thickness along a third direction perpendicular to the first direction and the second direction.

11. The semiconductor device of claim 8, further comprising:
a first isolating structure between the first contact structure and the second connection layer along a third direction perpendicular to the first direction and the second direction; and
a second isolating structure between the first contact structure and the third connection layer along the third direction,
wherein a thickness of the first isolating structure along the third direction is greater than a thickness of the second isolating structure along the third direction.

12. A semiconductor device, comprising:
a first stack of conductive layers and isolating layers alternating with each other along a first direction;
a second stack of dielectric layers and isolating layers alternating with each other along the first direction, wherein the second stack is adjacent to the first stack along a second direction perpendicular to the first direction;
a first contact structure extending in the second stack, wherein the first contact structure is coupled to a first conductive layer in the first stack; and
a second contact structure extending in the second stack, wherein the second contact structure is coupled to a second conductive layer in the first stack, and wherein a size of the second contact structure at a surface layer of the second stack is smaller than a size of the first contact structure at the surface layer of the second stack.

13. The semiconductor device of claim 12, wherein one or more first contact structures are arranged in a row along a third direction perpendicular to the first direction and the second direction, wherein the first contact structure and the second contact structure are arranged along a fourth direction perpendicular to the first direction and different from the third direction.

14. The semiconductor device of claim 13, further comprising a first gate line slit structure and a second gate line slit structure both extending along the third direction, wherein the first stack and the second stack are arranged between the first gate line slit structure and the second gate line slit structure, and
wherein more than one row of the first contact structures are arranged in the second direction between the first gate line slit structure and the second gate line slit structure.

15. The semiconductor device of claim 13, wherein the first contact structure is coupled to the first conductive layer through a first connection layer in the second stack,
wherein the second contact structure is coupled to the second conductive layer through a second connection layer in the second stack, and
wherein the second connection layer at least partially overlaps with the first connection layer in a plan view perpendicular to the first direction.

16. The semiconductor device of claim 15, wherein the first contact structure extends through the second connection layer along the first direction, and wherein at least one second contact structure is coupled to the second connection layer.

17. A method of forming a semiconductor device, the method comprising:
forming a first stack of conductive layers and isolating layers alternating with each other along a first direction;
forming a second stack of dielectric layers and isolating layers alternating with each other along the first direction, wherein the second stack is adjacent to the first stack along a second direction perpendicular to the first direction;
forming a first contact structure in the second stack, wherein the first contact structure reaches a first connection layer in the second stack, wherein the first connection layer is coupled to a first conductive layer in the first stack; and
forming a second contact structure in the second stack, wherein the second contact structure reaches a second connection layer in the second stack, wherein the second connection layer is coupled to a second conductive layer in the first stack,
wherein the first contact structure extends through the second connection layer.

18. The method of claim 17, wherein forming the first contact structure in the second stack comprises:
etching a first portion of the second stack to a first dielectric layer to form a first hole structure along the first direction;
removing the first dielectric layer and forming a first metal layer;
extending the first hole structure in the second stack along the first direction by etching the first metal layer to further etch a second portion of the second stack to a second dielectric layer;
removing the second dielectric layer and forming a second metal layer as the first connection layer; and
depositing one or more conductive layers in the first hole structure to be in contact with the first connection layer.

19. The method of claim 18, wherein etching the first metal layer comprises:
etching the first metal layer to be away from a bottom of the first hole structure along a third direction perpendicular to the first direction and the second direction,
wherein the method further comprises:
forming an isolating structure in the bottom of the first hole structure to be in contact with the etched first metal layer; and
etching the isolating structure to extend the first hole structure along the first direction.

20. The method of claim 18, wherein forming the second contact structure in the second stack comprises:
etching a third portion of the second stack to reach the first metal layer to form a second hole structure that is spaced from the first hole structure along the second direction; and
depositing the one or more conductive layers in the second hole structure to be in contact with the first metal layer as the second connection layer.
